(19) United States
(12) Patent Application Publication
(10) Pub. No.: US 2006/0027870 A1
(43) Pub. Date: Feb. 9, 2006

(54) Semiconductor device and method of manufacturing the same

(76) Inventor: Satoshi Inaba, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/100,559

(22) Filed: Apr. 7, 2005

(30) Foreign Application Priority Data
Aug. 5, 2004 (JP) 2004-229535

(51) Int. Cl. H01L 27/12

(52) U.S. Cl. 257/353

(57) ABSTRACT

A Fin-FET includes a support substrate, a buried insulation film provided on the support substrate, a fin part provided on the buried insulation film, the fin part being formed of a silicon layer and having mutually opposed side surfaces, and a gate electrode provided via an insulation film so as to cover at least a part of the side surfaces, wherein the gate electrode is provided to cover the part of the side surfaces of the fin part from a position lower than an interface between the support substrate and the buried oxide film.

### CROSS-REFERENCE TO RELATED APPLICATIONS

This application is based upon and claims the benefit of priority from prior Japanese Patent Application No. 2004-229535, filed Aug. 5, 2004, the entire contents of which are incorporated herein by reference.

### BACKGROUND OF THE INVENTION

1. Field of the Invention

The present invention relates generally to a semiconductor device and a method of manufacturing the same, and more particularly to a device structure that achieves a high performance by fine patterning of a device region in a semiconductor integrated circuit, and a method of fabricating the device structure.

2. Description of the Related Art

In recent years, as regards an LSI that is formed on a silicon substrate, a remarkable increase in performance is achieved by fine patterning of devices that are employed. This is because an improvement in performance of logic circuits or MOSFETs used in a memory device such as an SRAM is achieved by shrinkage in gate length or reduction in thickness of a gate insulation film according to so-called scaling rules.

At present, the following documents disclose double-gate fully depleted SOIMOSFETs, each of which is a kind of three-dimensional MIS semiconductor device and is configured such that a projection region is formed by cutting out an Si substrate into a fine strip using an SOI substrate, a gate electrode is crossed over the cut-out projection region of the Si substrate, and a channel region is formed at an upper surface and side surfaces of the projection region:
(1) Hisamoto, D. et al: “FinFET-A Self-Aligned Double-Gate MOSFET Scalable to 20 nm”
IEEE Trans. Electron Devices vol. 47, No. 12, pp. 2320-1215, (2000), and
(2) Huang, X. et al: “Sub-50 nm P-channel FinFET”
IEEE Trans. Electron Devices vol. 48, No. 5, pp. 880-886, (2001).

In general, in silicon RIE (Si-RIE) (Si-Reactive Ion Etching) that is used in forming a fin in a Fin-FET, an etching gas in the etching process is changed along the way between a gas that is suited to etch Si alone (the use of this gas provides a high Si etching rate but causes etching of an oxide film, too), and a gas that has a high etching selectivity ratio for a BOX film (Buried Oxide Film) in the SOI substrate (the use of this gas provides a low Si etching rate and causes no etching of an oxide film).

For example, the former gas is composed mainly of HBr, and the latter is composed mainly of HBr+O₂. In a process using a gas with an etching selectivity ratio for the BOX film, the silicon fin is etched with a taper when the Si is processed. Consequently, the processed fin has a forward taper shape and it is very difficult to obtain an ideal rectangular shape with vertical side surfaces.

Even where the gas that does not etch the BOX film is used, if the height of the fin decreases, it becomes difficult to control the timing of switching the gas. As a result, it is difficult to etch the fin without etching the BOX film. The BOX film is necessarily etched to some extent.

In this state, if a step of removing an etch deposit after RIE or a process using hydrofluoric acid, which is necessary as a pre-process for forming a gate insulation film, is performed, the amount of etch of the BOX film would increase. Moreover, since a wet-type process is an isotropic etching process, lateral etching would progress and, as a result, a gap would occur under the fin part. In this case, as disclosed in
(3) Yang, F-L. et al: “25 nm CMOS Omega FETs” International Electron Devices Meeting (IEDM) pp. 255-258, (2002)
   if a gate insulation film and a gate electrode are formed, polysilicon that becomes an electrode is formed such that it comes under the fin part. Consequently, there is a concern that electric field concentration due to the gate occurs at a corner of a bottom part of the fin and the corner becomes a parasitic MOSFET with a low threshold. This parasitic MOSFET is undesirable since it may lead to a hump in drain current characteristics in a sub-threshold region, or a shift in threshold.

Next, the aforementioned prior-art Fin-FET is described. As is shown in FIG. 13 that is a cross-sectional view immediately after Si-RIE, an SOI substrate is prepared, which comprises a support substrate 81, a BOX film 82 formed on the support substrate 81, and an Si film 83 formed on the BOX film 82. A mask material for Si-RIE is formed on the Si film 83 and is patterned. Using the patterned mask material 84 as a mask, the Si-RIE is performed.

In this case, in order to obtain an etching selectivity ratio between the BOX oxide film 82 and the Si film 83, the gas for RIE for the fin part is changed during the etching, thereby decreasing the etching amount of the oxide film. Then, the etched Si film 83, which becomes the fin part, has such a shape that the Si film 83 is tapered from an intermediate point. Consequently, the BOX film 82 is etched to some extent, and the lower corner has acute angles.

Thereafter, a process of removing the deposit that is produced by the Si-RIE and a wet process using HF (Hydrofluoric Acid) that is employed in a pre-process for forming a gate insulation film are performed. Due to these processes, an upper part of the BOX film 82 is also etched, and the lower part of the fin 83 is side-etched.

As a result, as shown in FIG. 14, when a gate electrode 86 is formed following formation of a gate insulation film 85, the gate electrode 86 extends into the fin part 83. If the gate electrode 86 is formed in such a shape, the gate electrode 86 surrounds the acute-angled lower corner portions of the fin part 83. If a voltage is applied to the gate electrode 86, electric field concentration occurs at the corner portions and a parasitic transistor with a threshold lower than the normal value is disadvantageously formed.

In any case, in the above-described prior-art Fin-FET, side etching occurs at the lower part of the fin that is formed of the Si region. If the gate electrode is formed in such a shape, an undesired parasitic transistor is formed due to electric field concentration since the fin part has acute-angled lower corner portions.

### BRIEF SUMMARY OF THE INVENTION

According to a first aspect of the present invention, there is provided a Fin-FET comprising: a support substrate; a buried insulation film provided on the support substrate; a fin part provided on the buried insulation film, the fin part being formed of a silicon layer and having mutually opposed side surfaces; and a gate electrode provided via an insulation film so as to cover at least a part of the side surfaces, wherein the gate electrode is provided to cover the part of the side surfaces of the fin part from a position lower than an interface between the support substrate and the buried oxide film.

According to a second aspect of the present invention, there is provided a semiconductor device comprising: a Fin-FET including a support substrate, a buried insulation film provided on the support substrate, a fin part provided on the buried insulation film, the fin part being formed of a first semiconductor layer and having mutually opposed side surfaces, and a first gate electrode provided via an insulation film so as to cover at least a part of the side surfaces, the first gate electrode being formed such that the first gate electrode covers the part of the side surfaces of the fin part from a position lower than an interface between the support substrate and the buried oxide film; and a planar MOSFET including at least one second semiconductor layer provided on the buried insulation film, the second semiconductor layer being formed of the same semiconductor material as the first semiconductor layer and being isolated from the fin part by a device isolation region, a second gate electrode formed via a gate insulation film in a longitudinal direction of the second semiconductor layer, and source/drain regions provided on both sides of the second gate electrode respectively.

According to a third aspect of the present invention, there is provided a semiconductor device comprising: a Fin-FET including a support substrate, a buried insulation film provided on the support substrate, a fin part provided on the buried insulation film, the fin part being formed of a first semiconductor layer and having mutually opposed side surfaces, and a first electrode provided via an insulation film so as to cover at least a part of the side surfaces, the first gate electrode being formed such that the first gate electrode covers the part of the side surfaces of the fin part from a position lower than an interface between the support substrate and the buried oxide film; a partially depleted SOIMOSFET including at least one second semiconductor layer with a first thickness, the second semiconductor layer being provided on the buried insulation film, being formed of the same semiconductor material as the first semiconductor layer, and being isolated from the fin part by an isolation region, a second gate electrode formed via a second gate insulation film in a longitudinal direction of the second semiconductor layer, and source/drain regions provided on both sides of the second gate electrode respectively; and a fully depleted SOIMOSFET including at least one third semiconductor layer with a second thickness less than the first thickness, the third semiconductor layer being provided on the buried insulation film, being formed of the same semiconductor material as the first semiconductor layer, and being isolated from the fin part by an isolation region, a third gate electrode formed via a third gate insulation film in a longitudinal direction of the third semiconductor layer, and source/drain regions provided on both sides of the third gate electrode respectively.

According to a fourth aspect of the present invention, there is provided a method of manufacturing a Fin-FET, comprising: preparing an SOI substrate including a support substrate, a buried insulation film provided on the support substrate, and a silicon layer provided on the buried insulation film; forming a mask on the silicon layer; processing the silicon layer by an RIE process on the SOI substrate without changing a gas such that the support substrate is removed to a desired depth through the buried insulation film to form a fin part; and forming a gate electrode via a gate insulation film so as to cover a part of mutually opposed side surfaces of the fin part from the support substrate.

### BRIEF DESCRIPTION OF THE DRAWING

FIGS. 1 to 6 are cross-sectional views that schematically illustrate steps of fabricating a fin part according to a first embodiment;

FIG. 7 is a cross-sectional view that schematically shows the fin part according to the first embodiment;

FIG. 8 is a perspective view that schematically shows a Fin-FET according to the first embodiment;

FIG. 9 is a cross-sectional view that schematically illustrates a fabrication step of the fin part according to the first embodiment;

FIG. 10 is a plan view that schematically shows a part of a Fin-FET/planar MOSFET hybrid semiconductor device according to a second embodiment;

FIG. 11 is a cross-sectional view that schematically shows a part of the Fin-FET/planar MOSFET hybrid semiconductor device according to the second embodiment;

FIG. 12 is a cross-sectional view that schematically shows a part of a hybrid semiconductor device according to the second embodiment, wherein a fin-FET, a partially depleted SOIMOSFET and a fully depleted SOIMOSFET are provided; and

FIGS. 13 and 14 are cross-sectional views that schematically show a prior-art fin part.

### DETAILED DESCRIPTION OF THE EMBODIMENTS

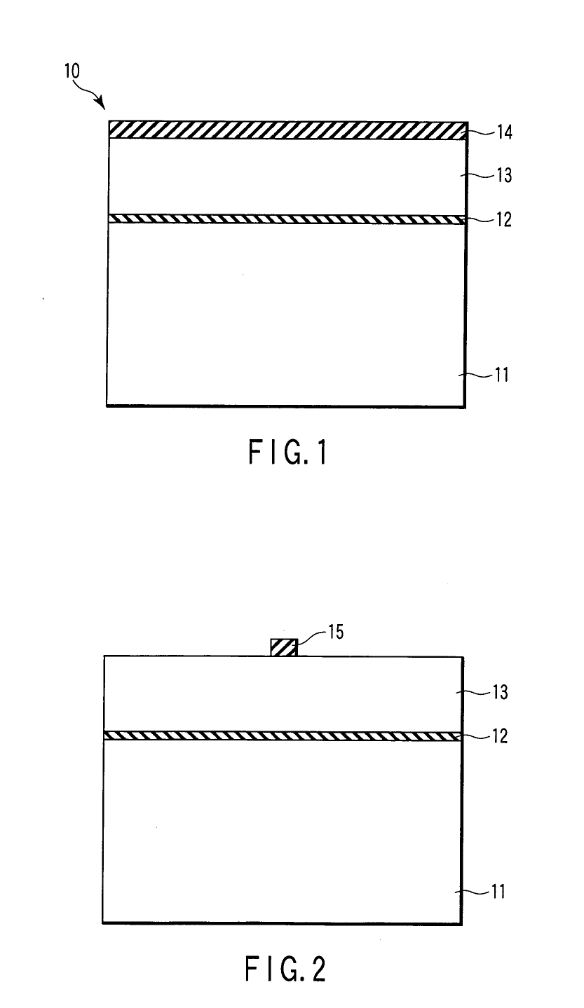

Referring now to FIGS. 1 to 8, a structure of a Fin-FET according to a first embodiment, as well as a method of manufacturing the Fin-FET, will be described. FIG. 1 shows an SOI substrate 10. The SOI substrate 10 comprises a support substrate 11 that is formed of silicon, a buried oxide film (BOX film) 12 that is formed on the support substrate 11 and has a thickness of 10 nm or less, preferably 5 to 10 nm, and a silicon (Si) film 13 that is formed on the oxide film 12 and has a thickness of 50 to 150 nm. The oxide film 12 may contain nitrogen atoms in order to control an etching rate in a wet process.

In order to form a fin part that is formed of the Si film 13, the Si film 13 is covered with a mask material 14 formed of a silicon nitride film having an etching selectivity ratio at a time of Si-RIE. Using a lithography technique, the mask material 14 is patterned to form a mask 15 as shown in FIG. 2. In this case, instead of the lithography technique using a resist material, a sidewall pattern transfer method, etc. may be applied.

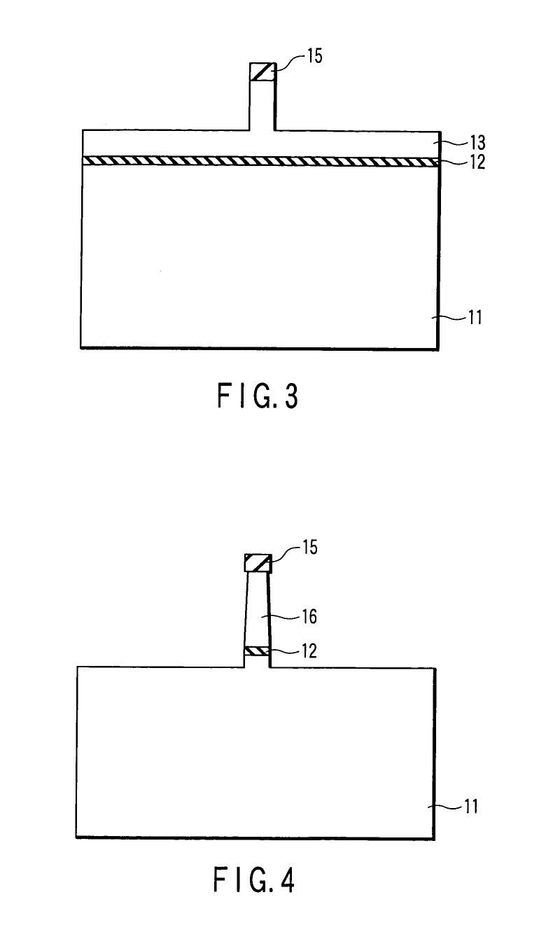

FIG. 3 shows a state in which the Si film 13 is partway etched by RIE using the mask 15. In the prior art, in order to obtain an RIE selectivity ratio between the Si film 13 and oxide film 12, the RIE condition relating to the gas is changed during etching so that the oxide film 12 may not easily be etched. By contrast, in the present embodiment, in order to form the structure while maintaining the verticality of the silicon, the RIE is continued using the gas of the single composition, without changing the gas. As is shown in FIG. 4, the RIE is continuously performed through the thin oxide film 12, i.e. the BOX film, until the support substrate 11 is removed to a desired depth. Thus, a fin part 16 is provided. Thereby, it can be possible to make the taper angle of the fin part 16 at about 88°, that is, it can be possible to obtain the fin part 16 having a substantially vertical shape. Both side surfaces of the fin part 16 become a channel of the Fin-FET.

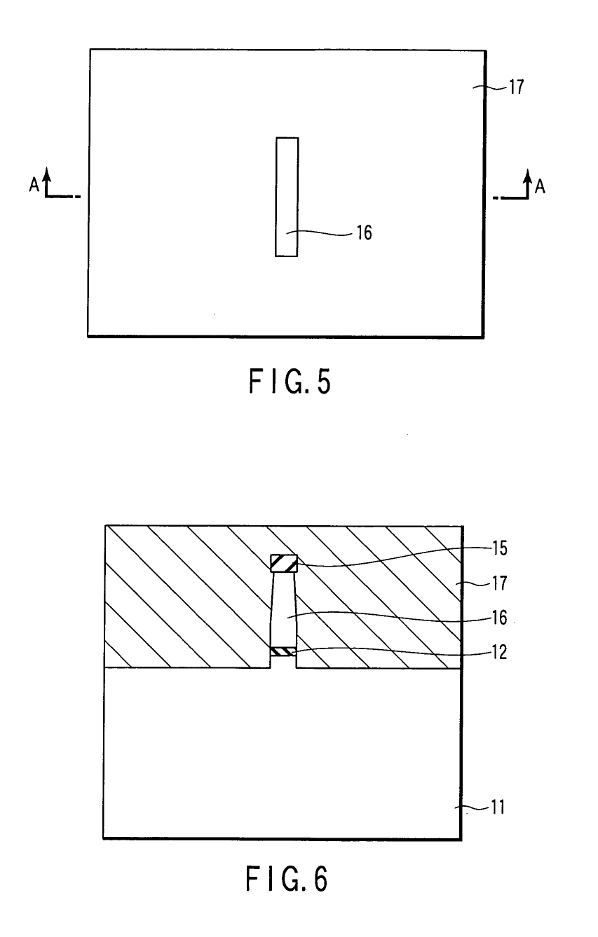

As is shown in a plan view of FIG. 5, a gate insulation film is formed over the exposed surface of the fin part 16, following which a gate electrode material 17, such as polysilicon, is deposited over the surface of the substrate. To facilitate lithography for a fine gate, the deposited gate electrode material is planarized so that a sufficiently fine pattern can be formed even where a lithography apparatus with a shallow DOF (Depth of Field) is used. Thus, a structure as shown in FIG. 6, which is taken along line A-A in FIG. 5, is obtained.

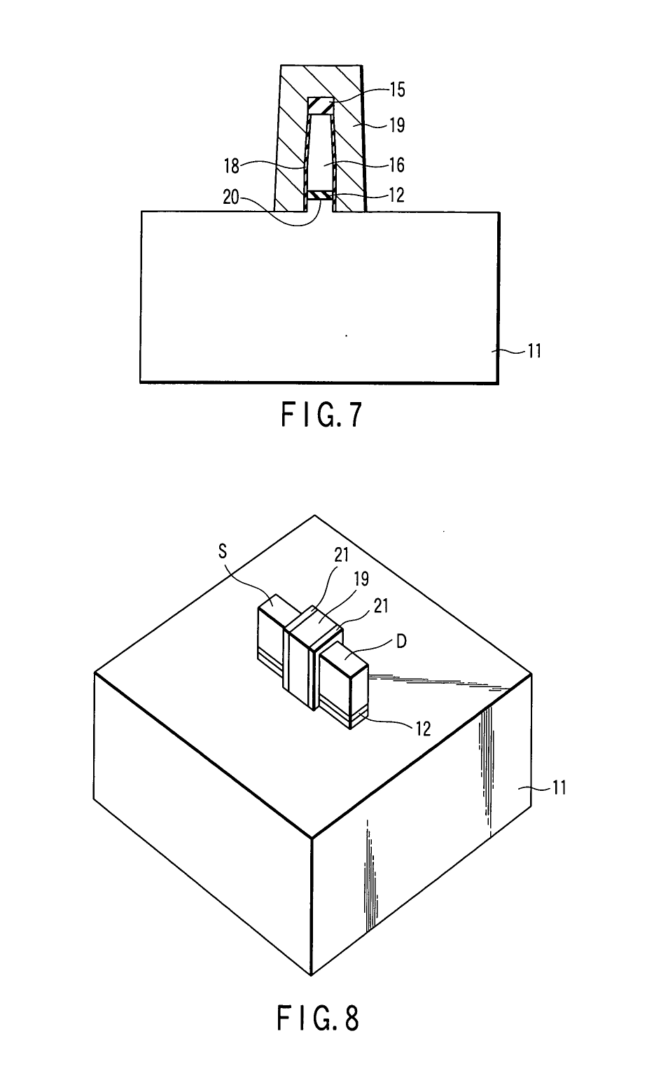

When the gate electrode material 17 is processed, not only the patterning using a resist, but also lithography by a sidewall transfer method using a mask material may be adopted as in the case of processing the silicon substrate. Further, the gate electrode material is processed using the resist pattern or the pattern of the mask material. By removing the used mask material or resist, a cross-sectional structure as shown in FIG. 7 is obtained.

Specifically, as shown in FIG. 7, parts of both side surfaces of the fin part 16 are covered with the gate electrode 19 via the gate insulation film 18. Further, the gate electrode 19 extends so as to cover the fin part 16 from a position lower than an interface 20 between the support substrate 11 and buried oxide film 12. The mask material 15 that is formed of a silicon nitride film, remains on top of the fin part 16 as a cap.

Thereafter, as shown in FIG. 8, like the formation of an ordinary Fin-FET, the device is completed through such fabrication steps as ion implantation in source/drain extensions, formation of gate side walls, ion implantation for source S/drain D, activation anneal, formation of a salicide film, deposition of an interlayer insulation film, and formation of contacts and metal wiring layers. FIG. 8 shows only the gate electrode 19, gate side walls 21, and source region S/drain region D.

The first embodiment has such a structure that the support substrate 11 is exposed. If ion implantation for forming the source/drain is performed following the gate RIE, the support substrate 11 is also doped. In this case, since the BOX film functions as an insulation film, no current path forms in the support substrate if contacts are formed only from the upper side of the Fin-FET, and no serious problem arises.

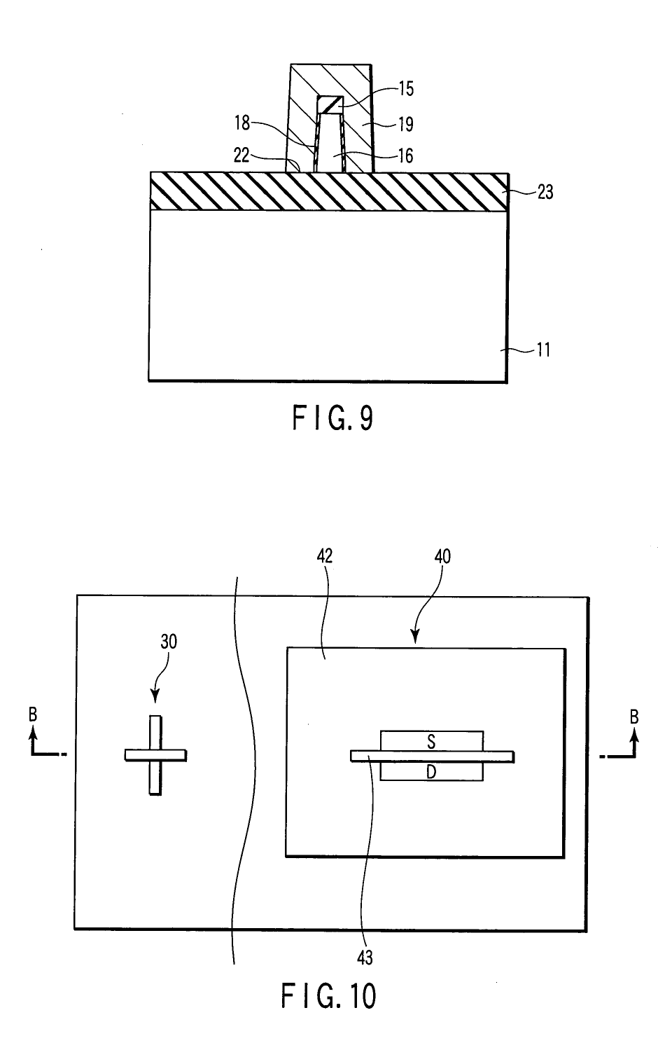

However, if the BOX film becomes very thin, a source/drain leak current through the BOX film may pose a problem in some cases. In such cases, as shown in FIG. 9, an insulation film 23 is buried at a bottom part of the fin up to a level higher than a boundary 22 between the BOX film 12 and fin part 16. Subsequently, ion implantation in the source/drain region is performed, and thus the problem of the leak current can be avoided. In this case, after the gate electrode is formed, an insulation film is deposited and etched back. Then, a gate sidewall material is deposited, and a gate sidewall with a desired thickness is formed, following which ion implantation is carried out. The insulation film 23 may be used as a device isolation region or an insulation film region, as will be described later.

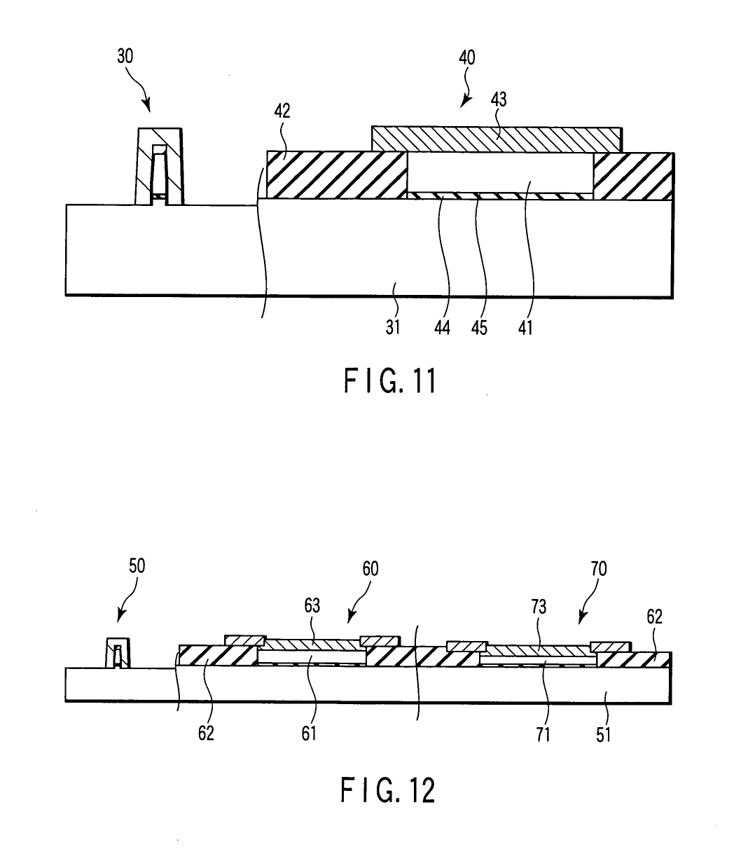

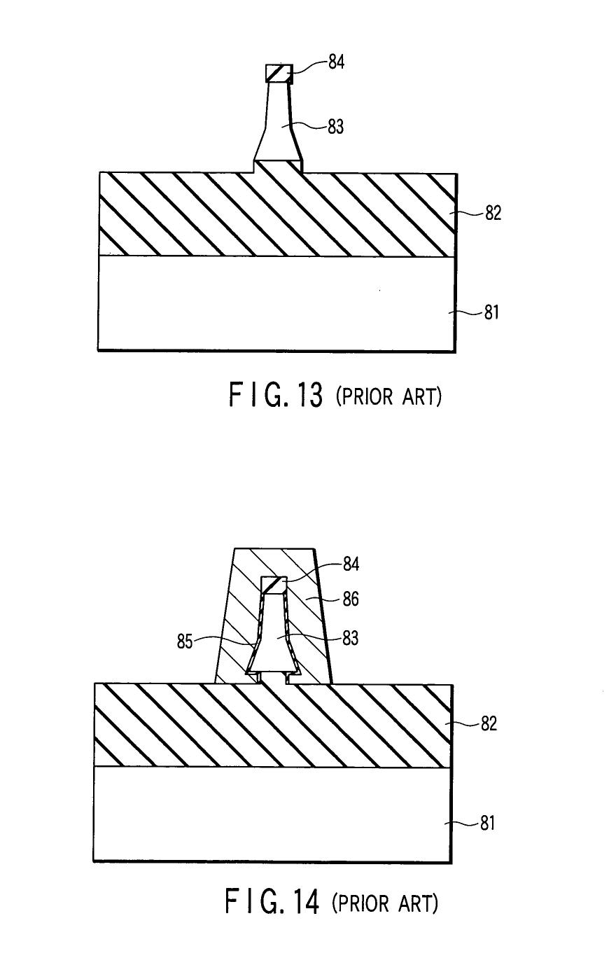

Next, a second embodiment is described. This embodiment relates to a hybrid semiconductor device which includes the above-described Fin-FET and a planar MOSFET. As is shown in a plan view of FIG. 10 and a cross-sectional view of FIG. 11, taken along line B-B in FIG. 10, a Fin-FET 30 and a planar MOSFET 40 are provided on a support substrate 31.

The Fin-FET 30 has the structure that has been described in connection with the first embodiment, so a detailed description is omitted. The planar MOSFET 40 has an SOI structure and is formed using a semiconductor layer 41. The planar MOSFET 40 is surrounded by a device isolation region 42 that is formed of the above-mentioned insulation layer 23.

A gate electrode 43 of the planar MOSFET 40 is formed in the longitudinal direction of the semiconductor layer 41 via a gate insulation film (not shown). The gate electrode 43 is formed on a level that is higher than at least an interface 45 between the semiconductor layer 41 and a buried insulation film 44. A source S and a drain D are formed on both sides of the gate electrode 43.

FIG. 12 shows a hybrid semiconductor device which includes a Fin-FET, a partially depleted SOIMOSFET and a fully depleted SOIMOSFET. Specifically, as shown in FIG. 12, a Fin-FET 50, which is the same as described above, a partially depleted SOIMOSFET 60 and a fully depleted SOIMOSFET 70 are mounted on a support substrate 51. A semiconductor layer 61 of the partially depleted SOIMOSFET 60 is greater in thickness than a semiconductor layer 71 of the fully depleted SOIMOSFET 70. These semiconductor layers are isolated from each other by a device isolation region 62 that is formed by the aforementioned insulation film 23.

As regards the semiconductor layers 61 and 71, there are optimal film thicknesses for respective operation modes. Desired semiconductor film thicknesses can be obtained by masking regions of the respective semiconductor layers 61 and 71 and performing a combination of an oxidizing step and an etching step.

Gate electrodes 63 and 73 are formed via gate insulation films (not shown) and, as in the case shown in FIG. 11, the gate electrodes 63 and 73 are formed on a level that is higher than at least the interface between the semiconductor layer 61, 71 and the buried insulation film.

In any case, as is clear from the first and second embodiments, since the process capable of easily processing the fin part is employed, a Fin-FET structure with a fin part having a near-ideal shape and a method of manufacturing the Fin-FET structure can be provided.

To be more specific, the fin part is formed by RIE using such a kind of gas that a vertical process can be performed through the buried insulation film down to a desired depth of the support substrate. Therefore, the verticality of the fin part is secured. In addition, the gate electrode is formed via the gate insulation film so as to extend from the support substrate and to cover parts of the mutually opposed side surfaces of the fin part. Therefore, a uniform electric field can be applied to the side surfaces of the fin part, and a Fin-FET with good cutoff characteristics can be realized. Furthermore, occurrence of an undesired parasitic transistor can be suppressed at the upper and lower parts of the gate electrode. Besides, since the thin BOX film is employed, the Fin-FET with the above-described structure can easily be formed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A Fin-FET comprising:
a support substrate;
a buried insulation film provided on the support substrate;
a fin part provided on the buried insulation film, the fin part being formed of a silicon layer and having mutually opposed side surfaces; and
a gate electrode provided via an insulation film so as to cover at least a part of the side surfaces,
wherein the gate electrode is provided to cover the part of the side surfaces of the fin part from a position lower than an interface between the support substrate and the buried oxide film.

2. The Fin-FET according to claim 1, wherein the buried insulation film has a thickness of 5 to 10 nm.

3. The Fin-FET according to claim 1, wherein the fin part has verticality to the support substrate.

4. The Fin-FET according to claim 1, wherein a part of the gate electrode is buried with an insulation film up to a level that is higher than a boundary between the buried insulation film and the fin part.

5. The Fin-FET according to claim 1, wherein a cap layer is provided on top of the fin part, to use only side surfaces of the fin part.

6. The Fin-FET according to claim 5, wherein the Fin-FET is a double-gate MOSFET.

7. The Fin-FET according to claim 1, wherein the gate electrode is perpendicular to a longitudinal direction of the fin part.

8. The Fin-FET according to claim 1, further comprising source/drain regions that are formed in the fin part such that the gate electrode is disposed between the source/drain regions.

9. A semiconductor device comprising:
a Fin-FET including a support substrate, a buried insulation film provided on the support substrate, a fin part provided on the buried insulation film, the fin part being formed of a first semiconductor layer and having mutually opposed side surfaces, and a first gate electrode provided via an insulation film so as to cover at least a part of the side surfaces, the first gate electrode being formed such that the first gate electrode covers the part of the side surfaces of the fin part from a position lower than an interface between the support substrate and the buried oxide film; and
a planar MOSFET including at least one second semiconductor layer provided on the buried insulation film, the second semiconductor layer being formed of the same semiconductor material as the first semiconductor layer and being isolated from the fin part by an isolation region, a second gate electrode formed via a second gate insulation film in a longitudinal direction of the second semiconductor layer, and source/drain regions provided on both sides of the second gate electrode respectively.

10. The semiconductor device according to claim 9, wherein the planar MOSFET is a partially depleted SOIMOSFET.

11. The semiconductor device according to claim 9, wherein the planar MOSFET is a fully depleted SOIMOSFET.

12. The semiconductor device according to claim 9, wherein the second gate electrode is formed on a level higher than an interface between the second semiconductor layer and the buried insulation film.

13. The semiconductor device according to claim 9, wherein the height of the first semiconductor layer is different from the height of the second semiconductor layer.

14. A semiconductor device comprising:
a Fin-FET including a support substrate, a buried insulation film provided on the support substrate, a fin part provided on the buried insulation film, the fin part being formed of a first semiconductor layer and having mutually opposed side surfaces, and a first electrode provided via an insulation film so as to cover at least a part of the side surfaces, the first gate electrode being formed such that the first gate electrode covers the part of the side surfaces of the fin part from a position lower than an interface between the support substrate and the buried oxide film;
a partially depleted SOIMOSFET including at least one second semiconductor layer with a first thickness, the second semiconductor layer being provided on the buried insulation film, being formed of the same semiconductor material as the first semiconductor layer, and being isolated from the fin part by an isolation region, a second gate electrode formed via a second gate insulation film in a longitudinal direction of the second semiconductor layer, and source/drain regions provided on both sides of the second gate electrode respectively; and
a fully depleted SOIMOSFET including at least one third semiconductor layer with a second thickness less than the first thickness, the third semiconductor layer being provided on the buried insulation film, being formed of the same semiconductor material as the first semiconductor layer, and being isolated from the fin part by an isolation region, a third gate electrode formed via a third gate insulation film in a longitudinal direction of the third semiconductor layer, and source/drain regions provided on both sides of the third gate electrode respectively.

15. The semiconductor device according to claim 14, wherein the second and third gate electrodes are provided on levels higher than interfaces between the second and third semiconductor layers and the buried insulation film, respectively.

16. The semiconductor device according to claim 14, wherein the height of the first semiconductor layer is different from the height of each of the second and third semiconductor layers.

17. A method of manufacturing a Fin-FET, comprising:
preparing an SOI substrate including a support substrate, a buried insulation film provided on the support substrate, and a silicon layer provided on the buried insulation film;
forming a mask on the silicon layer;
processing the silicon layer by an RIE process on the SOI substrate without changing a gas such that the support substrate is removed to a desired depth through the buried insulation film to form a fin part; and
forming a gate electrode via a gate insulation film so as to cover a part of mutually opposed side surfaces of the fin part from the support substrate.

18. The method according to claim 17, wherein nitrogen atoms are contained in the buried insulation film to control an etching rate in a wet process.

19. The method according to claim 17, wherein after the gate electrode is formed, an insulation film is deposited up to a level higher than an interface between the fin part and the buried insulation film.
